(19) United States
(12) Patent Application Publication
(10) Pub. No.: US 2015/0127890 A1
(43) Pub. Date: May 7, 2015

(54) MEMORY MODULE WITH A DUAL-PORT BUFFER

(71) Applicants: James W. Brainard, Cypress, TX (US); William C. Hallowell, Spring, TX (US); David G. Carpenter, Cypress, TX (US)

(72) Inventors: James W. Brainard, Cypress, TX (US); William C. Hallowell, Spring, TX (US); David G. Carpenter, Cypress, TX (US)

(73) Assignee: Hewlett-Packard Development Company, L.P., Houston, TX (US)

(21) Appl. No.: 14/400,787

(22) PCT Filed: Jun. 28, 2012
(86) PCT No.: PCT/US2012/044696

§ 371 Date: Nov. 12, 2014

(51) Int. Cl. G06F 3/06; G11C 7/10

(52) U.S. Cl. CPC G06F 3/0619; G06F 3/068; G06F 3/0647; G11C 7/1075
USPC 711/103

(57) ABSTRACT

A computer system includes a memory module. The memory module includes volatile memory, a non-volatile memory subsystem, a host port, and a dual-port buffer device. The dual-port buffer device synchronously couples the non-volatile memory subsystem and the host port to the volatile memory. The dual port buffer device includes routing logic to selectably route address information provided by the host port and the non-volatile memory subsystem to the volatile memory.

### BACKGROUND

Memory devices may be broadly classified as providing volatile or non-volatile storage. Volatile memory retains stored data only while power is applied. Non-volatile memory, however, retains information after power has been removed.

Random access memory (“RAM”) is one type of volatile memory. As long as the addresses of the desired cells of RAM are known, RAM may be accessed in any order. Dynamic random access memory (“DRAM”) is one type of RAM. In DRAM, a capacitor is used to store a memory bit, and the capacitor must be periodically refreshed to maintain a high electron state. Because the DRAM circuit is small and inexpensive, it may be used as memory for computer systems.

FLASH memory is one type of non-volatile memory. Generally, FLASH memory is accessible in blocks or pages. For example, a page of FLASH memory may be erased in one operation or one “flash.” Accesses to FLASH memory are relatively slow compared with accesses to DRAM. As such, FLASH memory may be used as long term, persistent, or secondary storage for computer systems, rather than as primary storage. Because of the different features and capabilities provided, DRAM and FLASH memory may be complementarily employed in a computer system.

### BRIEF DESCRIPTION OF THE DRAWINGS

For a detailed description of various examples of the invention, reference will now be made to the accompanying drawings in which:

FIG. 1 shows a block diagram for a hybrid memory module in accordance with principles disclosed herein;

FIG. 2 shows a block diagram for a hybrid memory module in accordance with principles disclosed herein;

FIG. 3 shows a block diagram for a computer system including a memory module in accordance with principles disclosed herein; and

FIG. 4 shows a flow diagram for a method for controlling data flow in a memory module in accordance with principles disclosed herein.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct connection, through an indirect connection via other devices and connection, or through a wireless connection. The recitation “based on” is intended to mean “based at least in part on.” Therefore, if X is based on Y, X may be based on Y and any number of other factors.

### DETAILED DESCRIPTION

The following discussion is directed to various implementations of memory modules and systems employing the memory modules. Although one or more of these implementations may be preferred, the implementations disclosed should not be interpreted, or otherwise used, as limiting the scope of the disclosure, including the claims. In addition, one skilled in the art will understand that the following description has broad application, and the discussion of any implementation is illustrative and is not intended to intimate that the scope of the disclosure, including the claims, is limited to that implementation.

The speed and functionality of computers is ever increasing. Higher speeds may be provided by increasing clock frequencies, which often dictate reduced signal transition times, and greater likelihood of signal induced noise from reflections and crosstalk. Expansion of functionality may require that an increasing number of components occupy a limited amount of space. Furthermore, adding components may increase signal line loading and compromise signal integrity.

Memory modules, such as the dual in-line memory module (DIMM), used in computing devices (such as computers) are subject to the above-mentioned advances in computer development. Electronic system and memory speed increases, and addition of functionality expanding components to the DIMM, can result in noise or signal degradation that limits module performance and/or form factor expansion that detrimentally affects module size. The memory modules disclosed herein include a dual-port buffer device that provides improved module noise immunity and supports additional module functionality without increasing the form factor of the module.

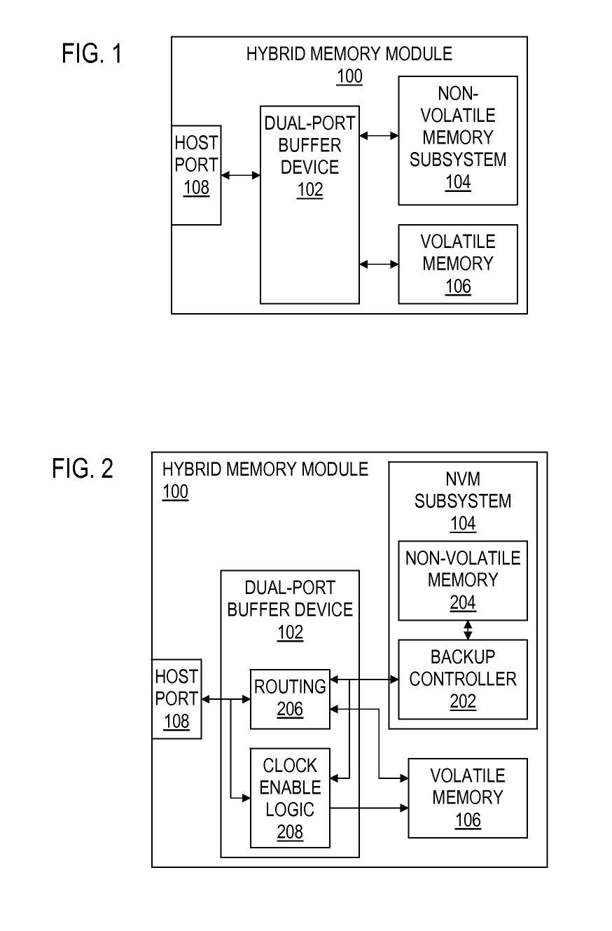

FIGS. 1 and 2 show block diagrams for a hybrid memory module 100 in accordance with principles disclosed herein. The hybrid memory module 100 may be implemented as a DIMM having a standard DIMM form factor (e.g., a 240 pin DIMM) for installation in a computer system. The hybrid memory module 100 includes a host port 108, a dual-port buffer device 102, volatile memory 106, and a non-volatile memory subsystem 104. The volatile memory 106 may include dynamic random access memory (DRAM). In DRAM, each data bit is stored as charge on a capacitor of a memory cell. To prevent loss of information as the capacitors gradually discharge due to leakage, the memory cells of the DRAM are periodically refreshed. Refresh operations may be externally controlled or the DRAM may execute a self-refresh procedure responsive to a command to enter a self-refresh mode. The volatile memory 106 may include multiple DRAM integrated circuits. For example, a memory module 100 may include two ranks of DRAM, each rank including nine 8-bit DRAMs to provide 64 data bits and 8 bits for error detection and correction. The volatile memory 106 may employ various types of DRAMs (e.g., double data rate (DDR) −2, −3, etc.). Some implementations of the volatile memory 106 may include volatile storage device technologies other than DRAM.

The non-volatile memory subsystem 104 provides backup storage for preservation of the data stored in volatile memory 106. The non-volatile memory subsystem 104 is shown in greater detail in FIG. 2. As shown in FIG. 2, the non-volatile memory subsystem 104 includes a backup controller 202 and non-volatile memory 204. The non-volatile memory 204 may include Flash memory, which stores bits in memory cells using floating-gate transistors. Implementations of the non-volatile memory 204 may include any type of Flash memory (e.g., NOR Flash, NAND Flash). Some implementations of the non-volatile memory 204 may include non-volatile memory technologies other than Flash memory (e.g., EEPROM, ferro-electric memory, magnetoresistive memory, phase-change memory, etc.).

The ratio of volatile memory 106 to non-volatile memory 204 in the memory module 100 may vary from implementation to implementation. For example, in some implementations the storage capacity of the non-volatile memory 204 may equal the storage capacity of the volatile memory 106. Other implementations of the memory module 100 may provide different volatile memory 106 to non-volatile memory 204 storage ratios.

The backup controller 202 is coupled to the non-volatile memory 204, and controls movement of data from the volatile memory 106 to the non-volatile memory 204 and vice versa. The backup controller 202 may move the data stored in volatile memory 106 to non-volatile memory 204 in the event of a power failure or other situation deemed likely result in loss of data stored in the volatile memory 106. The non-volatile memory subsystem 104 may include power fail detectors (e.g., power supply voltage level detectors) to detect imminent power loss. Detection of potential loss of data from the volatile memory 106 (e.g., imminent power loss) may trigger the backup controller 202 to copy data from the volatile memory 106 to the non-volatile memory 204. To facilitate backup of data, the memory module 100 may include access to a power source, such as a battery or charged super-capacitor, to power the memory module 100 for a time interval sufficient to move data from volatile memory 106 to non-volatile memory 204. In some implementations of the backup controller 202, copying of data from volatile memory 106 to non-volatile memory 204 may be triggered by expiration of a timer or another event. Similarly, the backup controller 204 restores data to the volatile memory 106 from the non-volatile memory 204 when a data loss event has passed (e.g., power is restored to operational levels).

The backup controller 202 may include a processor and internal storage for instructions and data. The processor may be a general-purpose microprocessor, microcontroller, or other suitable instruction execution devices known in the art. The processor may retrieve instructions from the internal storage, where the internal storage is a computer-readable medium, and execute the instructions to perform the operations described herein. For example, the instructions, when executed, may cause the processor to detect potential data loss and copy data stored in the volatile memory 106 to the non-volatile memory 204, restore data to volatile memory 106 from non-volatile memory 204, and the like.

The host port 108 provides an interface through which systems and components external to the memory module 100 access the memory and other components of the memory module 100. For example, a host processor, direct memory access engine, graphics processor, or other data processing unit of a computer system may access the memory module 100 via the host port 108 by asserting an address, a command (e.g., read, write, etc.), a data value, etc.

The host port 108, backup controller 202, and volatile memory 106 are coupled to the dual-port buffer device 102. The dual-port buffer device 102 selectively provides routing for data moving between the volatile memory 106 and either of the host port 108 and the backup controller 202. The dual port buffer device 102 may also include registers that buffer and synchronize data, address, and/or control signals provided to the volatile memory 106 from the host port 108 and/or the backup controller 202. The dual-port buffer device may be an integrated circuit that performs the functions described herein.

As shown in the example of FIG. 2, the dual-port buffer device 102 includes routing circuitry 206 and clock enable logic 208. The routing circuitry 206 selectively multiplexes or communicatively connects the host port 108 or the backup controller 202 to the volatile memory 106. Thus, the routing circuitry selectively provides exclusive access to the volatile memory 106 to the host port 108 or the backup controller 202. In some implementations, selection of the host port 108 or the backup controller 202 for connection to the volatile memory 106 may be controlled by the backup controller 202. For example, the backup controller 202 may assert a signal to the routing circuitry 206 that indicates that the backup controller 202 requires access to the volatile memory 106 (e.g., access to back up the contents of the volatile memory 106 to non-volatile memory 204). Assertion of such a signal may cause the routing circuitry 206 to disable host port access to the volatile memory 206 and enable backup controller access to the volatile memory 106 (e.g., until the backup controller negates the signal).

By routing and buffering signals to and from the volatile memory 106 in the dual-port buffer device 102, the memory module 100 avoids signal integrity issues that may occur with the use of external switches, multiplexers, and/or multiple bus masters (e.g., backup controller 202 and synchronization register) for accessing the volatile memory 106 from the host port 108 and the backup controller 202. Thus, the memory module 100 provides access to the volatile memory 106 for both external and on memory module bus masters with no degradation of signal integrity or additional use of memory module real estate.

In the memory module 100, the volatile memory 106 is partitioned into a number of lanes. For example, a 72-bit implementation of the volatile memory 106 may be partitioned into nine 8-bit lanes (byte lanes). The clock enable logic 208 of the dual-port buffer device 102 provides a plurality of clock enable signals, such that a different clock enable signal is provided for each lane of the volatile memory 106. The clock enable logic 208 controls assertion of the clock enable signals in accordance with a current access of the volatile memory 106. If the volatile memory 106 is being accessed via the host port 108, the clock enable logic 208 may assert clock enable signals to all lanes of the volatile memory 106. If the volatile memory 106 is being accessed via neither of the host port and the backup controller 202, then the clock enable logic 208 may negate clock enable signals to all lanes of the volatile memory, thereby enabling a self-refresh mode if the volatile memory 106 includes DRAMs.

The backup controller 202 may access fewer than all lanes of the volatile memory 106 at a time. For example, the backup controller 202 may access the volatile memory 106 one lane at time. To accommodate such operation, the clock enable logic 208 provides for individual control and assertion of clock enable signals to selected lanes of the volatile memory 106 based on lane selection information provided by the backup controller 202. For example, the backup controller 202 may assert signals that provide an address or other lane selection information to the clock enable logic 208 thereby identifying a lane of the volatile memory 106 to be accessed. In response, the clock enable logic 208 may assert a clock enable signal associated with the lane(s) selected by the backup controller 202.

To copy the contents of volatile memory 106 to non-volatile memory 204, the backup controller 202 asserts signals informing the dual-port buffer device 102 to connect the backup controller to the volatile memory 106, and designating which of the lanes of the volatile memory 106 are to be accessed. The dual port buffer device 102 disables host port accesses to the volatile memory 106, configures routing circuitry 206 for backup controller 202 access of volatile memory 106, and asserts the clock enable signals associated with the designated lanes while negating clock enable signals associated with lanes not designated. The backup controller 202 can then retrieve data from the designated lane(s) of volatile memory 106 and store the retrieved data in the non-volatile memory 204. Similar operations may be performed to restore data to the volatile memory 106 from the non-volatile memory 204.

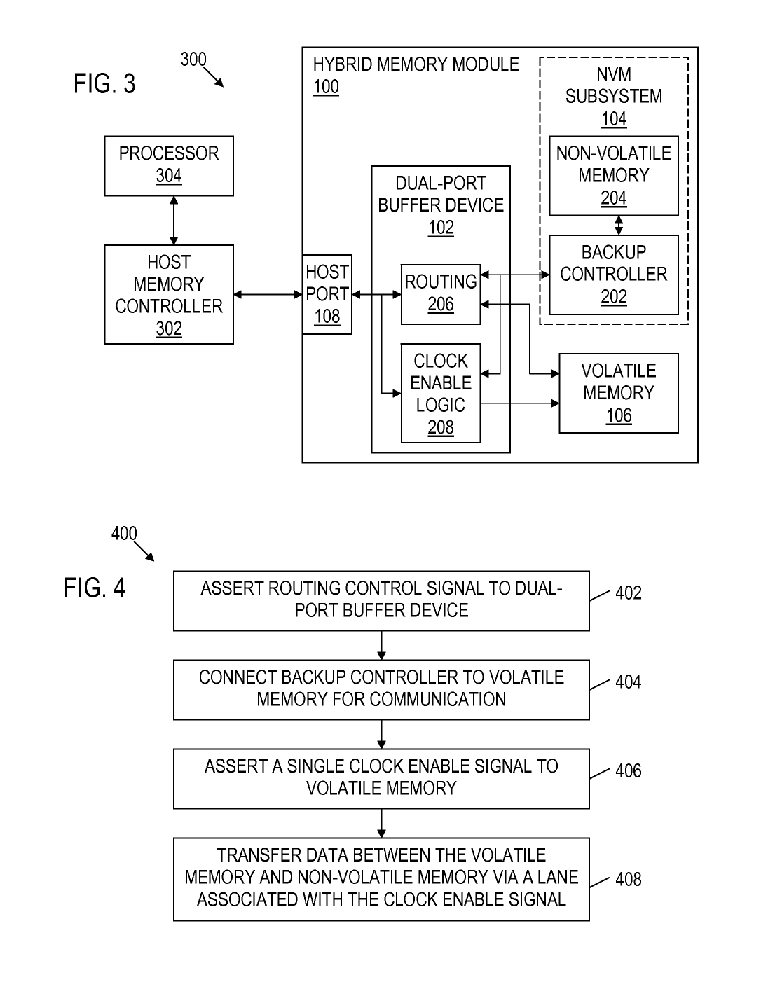

FIG. 3 shows a block diagram for a computing system 300 including the hybrid memory module 100 in accordance with principles disclosed herein. The computing system 300 may be any of various computing device configured to access the memory module 100 (e.g., desktop computers, servers, rack-mount computers, etc.) The computing system 300 also includes a host memory controller 302 and a processor 304. The host memory controller 302 coordinates the movement of data to and from the memory module 100 for devices external to the memory module 100. For example, the memory controller 302 may receive memory access requests directed to the volatile memory 106 from other components of the system 300, such as the processor 304, and assert signals to the host port 108 needed to effectuate the memory access.

The processor 304 may include, for example, one or more general-purpose microprocessors, digital signal processors, microcontrollers, graphics processors, direct memory access controllers, or other suitable instruction execution devices known in the art. Processor architectures generally include execution units (e.g., fixed point, floating point, integer, etc.), storage (e.g., registers, memory, etc.), instruction decoding, peripherals (e.g., interrupt controllers, timers, direct memory access controllers, etc.), input/output systems (e.g., serial ports, parallel ports, etc.) and various other components and sub-systems. The processor 304 may access the memory module 100 via the memory controller 302 for storage and/or retrieval of instructions and/or data.

FIG. 4 shows a flow diagram for a method 400 for controlling data flow in the memory module 100 in accordance with principles disclosed herein. Though depicted sequentially as a matter of convenience, at least some of the actions shown can be performed in a different order and/or performed in parallel. Additionally, some embodiments may perform only some of the actions shown. At least some of the operations of the method 400 can be performed by a processor (e.g., a processor of the backup controller 202) executing instructions read from a computer-readable medium.

In block 402, the backup controller 202 is preparing to access the volatile memory 106. The backup controller 202 asserts routing control signals to the dual-port buffer device 102. The routing control signals that backup controller 202 provide to the dual-port buffer device 102 cause the dual port buffer device 102 to allow the backup controller to access the volatile memory 106.

In block 404, the dual-port buffer device 102 sets the routing circuitry 206 in accordance with the routing control signals asserted by the backup controller 202. In accordance with routing control signals, the routing circuitry 206 is set to connect the backup controller 202 to the volatile memory 106 and to disconnect the host port 108 from the volatile memory 106. Thus, host port 108 access to the volatile memory 106 is disabled, and backup controller 204 access to the volatile memory 106 is enabled.

Because the backup controller 204 may simultaneously access fewer than all the lanes of the volatile memory 106, the routing control signals asserted by the backup controller 204 may also designate a particular lane or lanes of the volatile memory 106 to be accessed. In block 406, the clock enable logic 208 of the dual-port buffer device 102 asserts a clock enable signal to the designated lane(s) of the volatile memory 106. The clock enable logic 208 negates the clock enable signals to all lanes not designated by the backup controller 204.

In block 408, the backup controller 204 transfers data between the volatile memory 106 and the non-volatile memory 204 via the lane(s) associated with the clock enable signal(s) asserted by the dual-port buffer device 102. The backup controller 202 may move data from volatile memory 106 to non-volatile memory 204 or vice versa. The backup controller 202 may repeat the operations described above to access additional lanes of the volatile memory 106.

When access of the volatile memory 106 by the backup controller 202 is complete, the dual-port buffer device 102 may set the routing circuitry 206 and the clock enable logic 208 to allow access to the volatile memory 106 via the host port 108.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A computing system, comprising:
a memory module, comprising:
volatile memory;
a non-volatile memory subsystem;
a host port; and
a dual-port buffer device to synchronously couple the non-volatile memory subsystem and the host port to the volatile memory, the dual port buffer device comprising routing logic to selectably route address information provided by the host port and the non-volatile memory subsystem to the volatile memory.

2. The computing system of claim 1 wherein the routing logic is to:
selectably route data information provided by the host port and the non-volatile memory subsystem to the volatile memory; and
selectably route data information read from the volatile memory to the host port and the non-volatile memory subsystem.

3. The computing system of claim 1, wherein the volatile memory is partitioned into a plurality of byte-lanes; wherein the dual-port buffer device comprises clock enable logic to:
provide a different clock enable signal for each of the byte-lanes; and
selectably assert one of the clock enable signals while negating the other clock enable signals to enable one of the byte-lanes for access by the non-volatile memory subsystem while disabling all of the other byte-lanes.

4. The computing system of claim 3, wherein the non-volatile memory subsystem comprises non-volatile memory, and the non-volatile memory subsystem is to move data between the volatile memory and the non-volatile memory one byte-lane at a time.

5. The computing system of claim 3, wherein the dual-port buffer device is to provide a same data and address to each of the byte-lanes while the one of the clock enable signals is selectably asserted

6. The computing system of claim 1, further comprising a host memory controller to access the volatile memory via the host port.

7. A method, comprising:
asserting, by a backup controller of a memory module, a routing control signal to a dual-port buffer device of the memory module;
communicatively connecting the backup controller to volatile memory of the memory module responsive to the asserting;
asserting a selected one of a plurality of clock enable signals, by the dual-port buffer device, to the volatile memory;
transferring, by the backup controller, data between the volatile memory and a non-volatile memory of the memory module via a single byte-lane associated with the selected one of the clock enable signals.

8. The method of claim 7, further comprising disabling host memory controller access to the volatile memory responsive to the asserting of the routing control signal.

9. The method of claim 7, further comprising negating all of the plurality of clock enable signals other than the selected one of the clock enable signals.

10. The method of claim 7, wherein asserting the routing control signal comprises asserting, by the backup controller, a clock selection signal, to the dual-port buffer device, that identifies the selected one of the plurality of clock enable signals.

11. A memory module, comprising:
volatile memory arranged for access via a plurality of byte-lanes;
non-volatile memory;
a backup controller to copy data from the volatile memory to the non-volatile memory responsive to detection of an event indicative of potential loss of data in the volatile memory;
a host port; and
a dual-port buffer device to generate a plurality of clock enable signals, each of the clock enable signals corresponding to one of the byte lanes;
wherein the backup controller is to indicate, to the dual-port buffer device, which of the byte-lanes is to be used to transfer data from the volatile memory to the non-volatile memory; and
wherein the dual-port buffer device is to assert the clock enable signal corresponding to the indicated byte-lane and negate each other of the clock enable signals.

12. The memory module of claim 11, wherein the dual-port buffer device is to selectively route data and address signals between the volatile memory and a selected one of the host port and the backup controller.

13. The memory module of claim 11, wherein the dual port buffer device is to synchronize data and address signals routed to the volatile memory.

14. The memory module of claim 11, wherein the dual port buffer is configured to disable access to the volatile memory via the host port while the backup controller is accessing the volatile memory.

15. The memory module of claim 11, wherein the dual-port buffer device is to:
assert a plurality of clock enable signals in conjunction with volatile memory access via the host port; and
negate all clock enable signals to refresh the volatile memory;
